(19) United States
(12) Patent Application Publication
(10) Pub. No.: US 2025/0070072 A1
(43) Pub. Date: Feb. 27, 2025

(54) SEMICONDUCTOR PACKAGE COMPRISING DAM AND MULTI-LAYERED UNDER-FILL LAYER

(71) Applicant: SAMSUNG ELECTRONICS CO., LTD., Suwon-si (KR)

(72) Inventors: Seongyo KIM, Suwon-si (KR); MINSOO KIM, Suwon-si (KR); SANG-SICK PARK, Suwon-si (KR)

(73) Assignee: SAMSUNG ELECTRONICS CO., LTD., Suwon-si (KR)

(21) Appl. No.: 18/640,576

(22) Filed: Apr. 19, 2024

(30) Foreign Application Priority Data
Aug. 21, 2023 (KR) 10-2023-0108994

(51) Int. Cl. H01L 23/00; H01L 23/31; H01L 23/48; H01L 25/065

(52) U.S. Cl. CPC H01L 24/32; H01L 23/3107; H01L 23/481; H01L 24/16; H01L 24/27; H01L 24/29; H01L 24/33; H01L 24/73; H01L 24/92; H01L 25/0657; H01L 2224/16145; H01L 2224/26145; H01L 2224/27614; H01L 2224/29017; H01L 2224/2929; H01L 2224/29386; H01L 2224/2939; H01L 2224/32145; H01L 2224/3303; H01L 2224/73204; H01L 2224/9211; H01L 2225/06568; H01L 2924/05442

(57) ABSTRACT

A semiconductor package includes a first semiconductor die, a first under-fill layer on an upper surface of the first semiconductor die, a second under-fill layer on the first under-fill layer, a second semiconductor die provided on the second under-fill layer, and a mold layer on side surfaces of the second semiconductor die, the second under-fill layer, and the upper surface of the first semiconductor die. The first semiconductor die includes a first substrate, a first redistribution pattern on the first substrate, a first redistribution dielectric layer provided on the first redistribution pattern, and a first dam on the first redistribution dielectric layer and along an edge of the first substrate, and the first under-fill layer contacts a side surface of the first dam.

### CROSS-REFERENCE TO RELATED APPLICATION

This application claims priority under 35 U.S.C. § 119 to Korean Patent Application No. 10-2023-0108994, filed on Aug. 21, 2023, in the Korean Intellectual Property Office, the disclosure of which is incorporated by reference herein in its entirety.

### BACKGROUND

The present disclosure relates to a semiconductor package, and more specifically, to a semiconductor package including a dam and a multi-layered under-fill layer.

Integrated circuit chips are typically provided with a semiconductor package so as to be suitably applied to circuit boards of electronic products or to be otherwise combined within an electronic system. In a typical semiconductor package, an integrated circuit chip (or a semiconductor chip) may be mounted on a printed circuit board (PCB) and may be electrically connected to the PCB through bonding interconnection lines or bumps. Various research for improving the reliability and the durability of semiconductor packages has been conducted with the development of electronic industry.

### SUMMARY

One or more example embodiments provide a semiconductor package with improved reliability.

The problems to be solved by one or more example embodiments is not limited to the problems mentioned above, and it will be apparent to those skilled in the art that one or more example embodiments may address other problems not mentioned. Further, one or more example embodiments may not address any of the problems mentioned.

According to an aspect of an example embodiment, a semiconductor package includes: a first semiconductor die; a first under-fill layer on an upper surface of the first semiconductor die; a second under-fill layer on the first under-fill layer; a second semiconductor die on the second under-fill layer; and a mold layer provided on side surfaces of the second semiconductor die, side surfaces of the second under-fill layer, and the upper surface of the first semiconductor die, wherein the first semiconductor die includes: a first substrate; a first redistribution pattern on the first substrate; a first redistribution dielectric layer on the first redistribution pattern; and a first dam on the first redistribution dielectric layer and along an edge of the first substrate, and the first under-fill layer contacts a side surface of the first dam.

According to a further aspect of an example embodiment, a semiconductor package includes: a first semiconductor die; a first under-fill layer on an upper surface of the first semiconductor die; a second under-fill layer on the first under-fill layer; a second semiconductor die on the second under-fill layer; an internal connection member in the second under-fill layer and connecting the first semiconductor die and the second semiconductor die; and a mold layer on side surfaces of the second semiconductor die, the second under-fill layer, and the upper surface of the first semiconductor die, wherein the first semiconductor die includes: a first substrate; a first redistribution pattern on the first substrate; a first redistribution dielectric layer on the first redistribution pattern; a first dam on the first redistribution dielectric layer and along an edge of the first substrate; a second redistribution pattern including a via portion penetrating the first redistribution dielectric layer and in contact with the first redistribution pattern, and a pad portion on the first redistribution dielectric layer; and a conductive pattern on the second redistribution pattern, wherein the first under-fill layer contacts a side surface of the first dam, wherein the first semiconductor die has a first width in a width direction, wherein the first under-fill layer has a second width in the width direction that is smaller than the first width, wherein the second under-fill layer has a third width in the width direction that is smaller than the second width, and wherein the second semiconductor die has a fourth width in the width direction that is smaller than the third width.

According to an aspect of an example embodiment, a semiconductor package includes: a first semiconductor die; a first under-fill layer on an upper surface of the first semiconductor die; a second under-fill layer on the first under-fill layer; a second semiconductor die on the second under-fill layer; and a mold layer on side surfaces of the second semiconductor die, side surfaces of the second under-fill layer, and the upper surface of the first semiconductor die, wherein an upper surface of the first under-fill layer has a first surface roughness, and an upper surface of the second under-fill layer has a second surface roughness that is less rough than the first surface roughness.

### BRIEF DESCRIPTION OF THE DRAWINGS

The above and other aspects and features will be more apparent from the following description of example embodiments taken in conjunction with the accompanying drawings, in which:

FIG. 1 is a plan view of a semiconductor package according to one or more example embodiments;

FIG. 2 is a cross-sectional view taken along line A-A′ of FIG. 1 according to one or more example embodiments;

FIGS. 3A and 3B are enlarged views of portion ‘P1’ of FIG. 2 according to one or more example embodiments;

FIGS. 4A, 4B, 4C, 4D, 4E, 4F, 4G and 4H are views sequentially illustrating a process for manufacturing the semiconductor package of FIG. 2 according to one or more example embodiments;

FIG. 5 is an enlarged view of ‘P2’ in FIG. 4C, according to one or more example embodiments;

FIGS. 6A, 6B and 6C are views sequentially illustrating a process for manufacturing the semiconductor package of FIG. 2 according to one or more example embodiments;

FIGS. 7A, 7B and 7C are enlarged views of portion ‘P1’ of FIG. 2 according to one or more example embodiments;

FIGS. 8A, 8B, 8C and 8D are views sequentially illustrating the process of manufacturing the semiconductor package of FIG. 7A;

FIGS. 9A and 9B are enlarged views of portion ‘P1’ of FIG. 2 according to one or more example embodiments;

FIGS. 10A, 10B, 10C and 10D are views sequentially illustrating the process of manufacturing the semiconductor package of FIG. 9A;

FIG. 11 is a cross-sectional view of a semiconductor package according to one or more example embodiments;

FIG. 12 is a cross-sectional view of a semiconductor package according to one or more example embodiments;

FIG. 13 is a cross-sectional view of a semiconductor package according to one or more example embodiments;

FIG. 14 is a cross-sectional view of a semiconductor package according to one or more example embodiments;

FIG. 15 is a cross-sectional view of a semiconductor package according to one or more example embodiments; and

FIG. 16 is a cross-sectional view of a semiconductor package according to one or more example embodiments.

### DETAILED DESCRIPTION

Hereinafter, example embodiments will be described in detail with reference to the accompanying drawings. Herein, terms indicating order such as first, second, and so on may be used to distinguish components that perform the same/similar functions, and their numbers may change depending on the order in which they are mentioned.

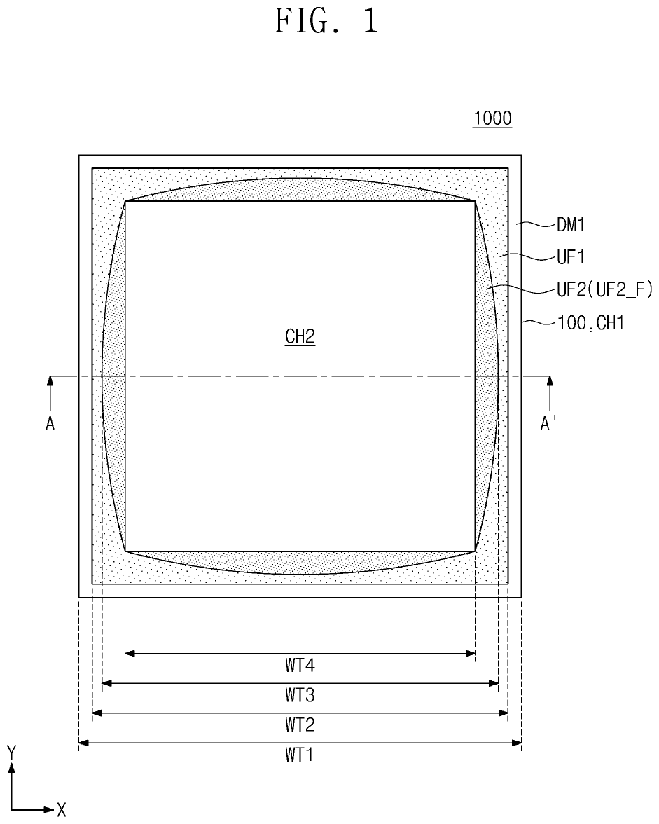

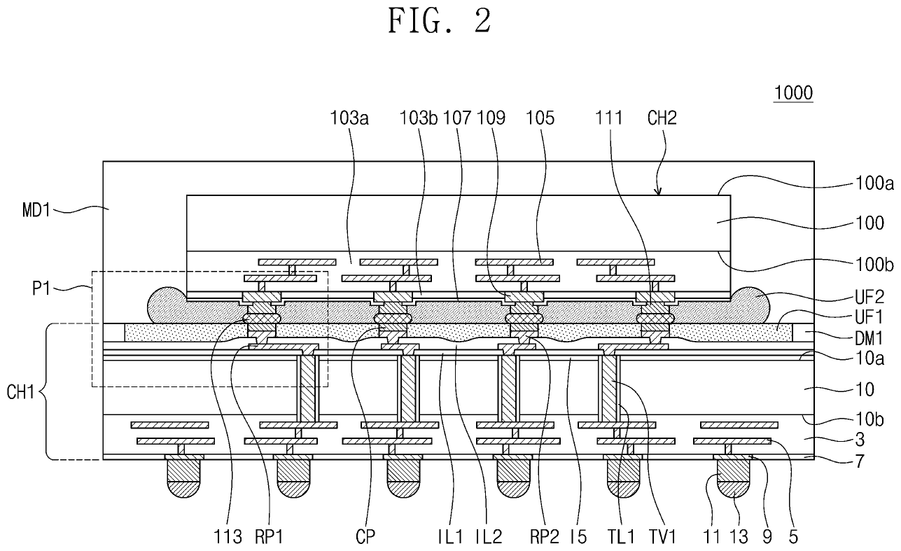

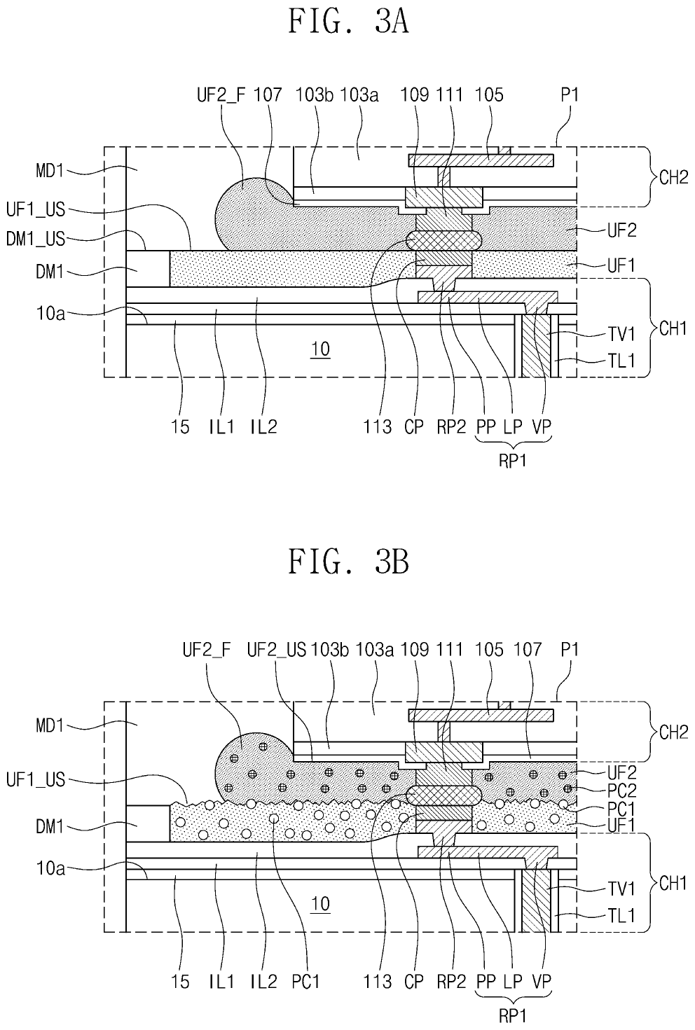

FIG. 1 is a plan view of a semiconductor package according to one or more example embodiments. FIG. 2 is a cross-sectional view taken along line A-A′ of FIG. 1 according to one or more example embodiments. FIGS. 3A and 3B are enlarged views of portion ‘P1’ of FIG. 2 according to one or more example embodiments.

Referring to FIGS. 1, 2, 3A, and 3B, a semiconductor package 1000 according to one or more example embodiments comprise a first semiconductor die CH1, a first under-fill layer UF1, a second under-fill layer UF2, a second semiconductor die CH2 that are sequentially stacked and a first mold layer MD1 covering them. For example, the first mold layer MD1 may include an insulating resin such as an epoxy-based molding compound (EMC). The first mold layer MD1 may further include a filler, and the filler may be dispersed in the insulating resin. Herein, ‘semiconductor die’ may also be referred to as ‘semiconductor chip’. The first semiconductor die CH1 and the second semiconductor die CH2 may each independently be a memory die, a logic circuit die, or a buffer die.

The first semiconductor die CH1 includes a first substrate 10. The first substrate 10 may be a silicon single crystal substrate or a silicon on insulator (SOI) substrate. The first substrate 10 may include a front surface 10b and a back surface 10a that face or oppose each other. A first interlayer insulating layer 3 may be disposed on the front surface 10b of the first substrate 10. The first interlayer insulating layer 3 may have a single-layer or multi-layer structure of at least one of silicon oxide, silicon nitride, silicon oxynitride, and porous insulator.

First transistors and multi-layered first interconnection lines 5 may be disposed in the first interlayer insulating layer 3. First conductive pads 9 may be disposed below the first interlayer insulating layer 3. First conductive bumps 11 may be bonded to the first conductive pads 9, respectively. The first interconnection lines 5, first conductive pads 9, and first conductive bumps 11 may each include at least one metal selected from aluminum, tungsten, copper, titanium, and tantalum. A first solder layer 13 may be bonded below the first conductive bumps 11. The first solder layer 13 may also be called an ‘external connection terminal’. The first solder layer 13 may be formed of SnAg, for example. A lower surface of the first interlayer insulating layer 3 may be covered with a first passivation layer 7. The first passivation layer 7 may have a single-layer or multi-layer structure of at least one of SiN, SiCN, and polyimide.

The back surface 10a of the first substrate 10 may be covered with a first backside insulating layer 15. The first backside insulating layer 15 may be formed of, for example, silicon oxide. A first through via TV1 may penetrate a portion of the first backside insulating layer 15, the first substrate 10, and the first interlayer insulating layer 3. The first through via TV1 may include a metal such as copper or tungsten. A first via insulating layer TL1 may be interposed between the first through via TV1 and the first substrate 10. The first via insulating layer TL1 may be formed of silicon oxide. An air gap may be disposed within the first via insulating layer TL1.

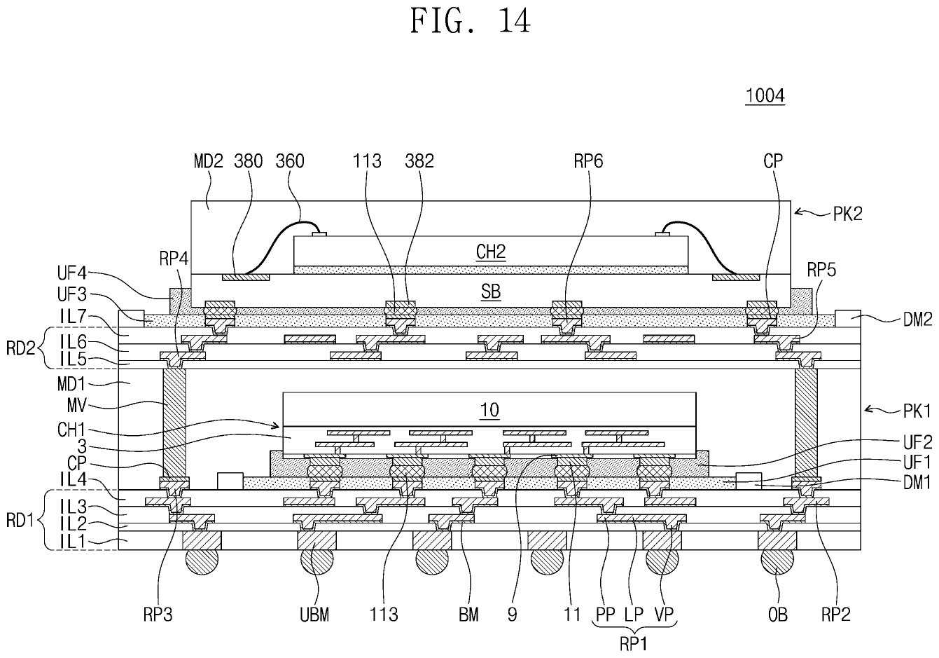

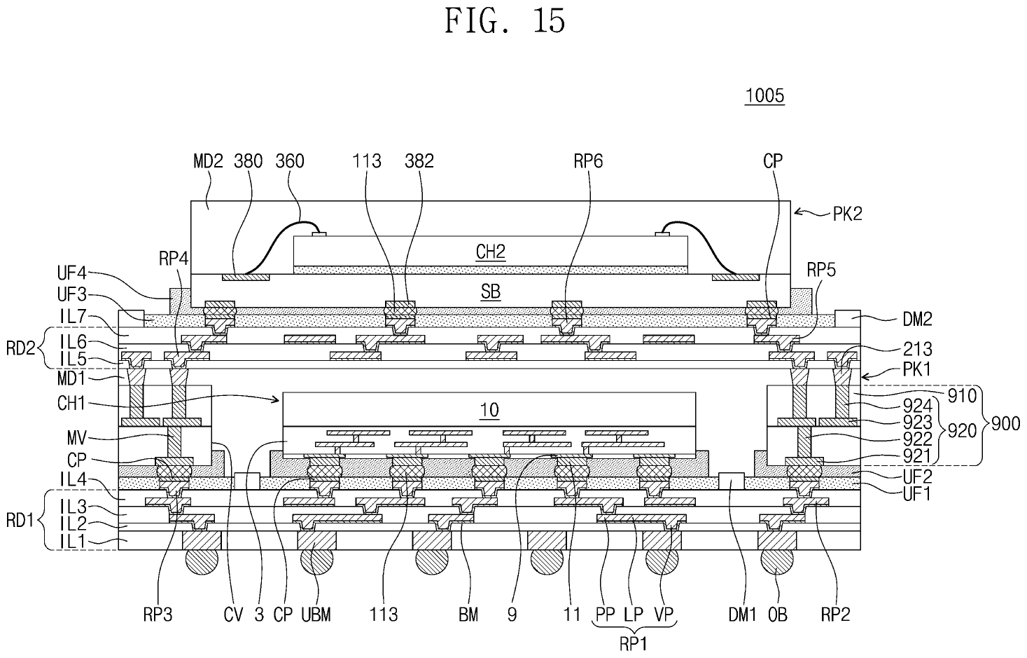

A first redistribution dielectric layer IL1 and a second redistribution dielectric layer IL2 are sequentially stacked on the first backside insulating layer 15. The first redistribution dielectric layer IL1 and the second redistribution dielectric layer IL2 may comprise a photo-imageable dielectric (PID) resin. A first redistribution pattern RP1 is disposed between the first redistribution dielectric layer IL1 and the second redistribution dielectric layer IL2. A second redistribution pattern RP2 is disposed on the second redistribution dielectric layer IL2. The first redistribution pattern RP1 and the second redistribution pattern RP2 may each include a metal such as copper. According to one or more example embodiments, lower surfaces of the first and second redistribution patterns RP1 and RP2 may be covered with a diffusion barrier layer (BM in FIG. 14). The diffusion barrier layer may include at least one of titanium, titanium nitride, tantalum, tantalum nitride, and tungsten nitride. Each of the first redistribution pattern RP1 and the second redistribution pattern RP2 may have a via portion VP, a line portion LP, and a pad portion PP. The via portion VP may have a width that narrows as the via portion VP goes downward.

The via portion VP of the first redistribution pattern RP1 may penetrate the first redistribution dielectric layer IL1 and may be in contact with the first through via TV1. The line portion LP and the pad portion PP of the first redistribution pattern RP1 are disposed between the first redistribution dielectric layer IL1 and the second redistribution dielectric layer IL2.

The via portion VP of the second redistribution pattern RP2 may penetrate the second redistribution dielectric layer IL2 and may be in contact with the pad portion PP of the first redistribution pattern RP1. The line portion LP and the pad portion PP of the second redistribution pattern RP2 are disposed on the second redistribution dielectric layer IL2. A second conductive pad CP is disposed on the pad portion PP of the second redistribution pattern RP2. The second conductive pad CP may include at least one metal selected from gold and nickel. The second conductive pad CP may also be called a ‘wetting layer.’

The first semiconductor die CH1 according to one or more example embodiments further includes a first dam DM1 disposed on an edge of the second redistribution dielectric layer IL2. The first dam DM1 may be formed of a single-layer or multi-layer structure of at least one of a conductive material and an insulating material. According to one or more example embodiments, the first dam DM1 may be formed with the same PID as the second redistribution dielectric layer IL2. An interface may or may not exist between the first dam DM1 and the second redistribution dielectric layer IL2. As illustrated in FIG. 1, when viewed in a plan view, the first dam DM1 may be disposed in a closed curve shape along an edge of the first semiconductor die CH1.

The second semiconductor die CH2 may include a second substrate 100. The second substrate 100 may be a silicon single crystal substrate or a silicon on insulator (SOI) substrate. The second substrate 100 may include a front surface 100b and a back surface 100a that face or oppose each other. Second and third interlayer insulating layers 103a and 103b may be sequentially disposed on a bottom surface of the front surface 100b of the second substrate 100. The second and third interlayer insulating layers 103a and 103b may each have a single-layer or multi-layer structure of at least one of silicon oxide, silicon nitride, silicon oxynitride, and porous insulator.

First transistors and multi-layered second interconnection lines 105 may be disposed in the second interlayer insulating layer 103a. Third conductive pads 109 may be disposed below the second interlayer insulating layer 103a. A lower surface of the third interlayer insulating layer 103b may be covered with a second passivation layer 107. The second passivation layer 107 may cover side surfaces and a portion of bottom surfaces of the third conductive pads 109. Second conductive bumps 111 may penetrate the second passivation layer 107 and may be bonded to the third conductive pads 109, respectively. The second conductive bumps 111 of the second semiconductor die CH2 may be bonded to the second conductive pads CP of the first semiconductor die CH1 by second solder layers 113. The second solder layer 113 may also be called an ‘internal connection member’.

The second interconnection lines 105, third conductive pads 109, and second conductive bumps 111 may each include at least one metal selected from aluminum, tungsten, copper, titanium, and tantalum. The second solder layer 113 may be formed of SnAg, for example. The second passivation layer 107 may have a single-layer or multi-layer structure of at least one of SiN, SiCN, and polyimide.

The first under-fill layer UF1 may be disposed on the second redistribution dielectric layer IL2 and in the first dam DM1. The first under-fill layer UF1 may cover an upper surface of the second redistribution dielectric layer IL2, a side surface of the first dam DM1, and side surfaces of the second redistribution pattern RP2 and second conductive pad CP. An upper surface UF1_US of the first under-fill layer UF1 may be coplanar with an upper surface DM1_US of the first dam DM1.

The second under-fill layer UF2 may be interposed between the first under-fill layer UF1 and the second semiconductor die CH2 and may cover side surfaces of the second conductive bump 111 and the second solder layer 113. A fillet portion UF2_F, which is a portion of the second under-fill layer UF2, may protrude outside a side surface of the second semiconductor die CH2. A side surface of the fillet portion UF2_F of the second under-fill layer UF2 may be rounded, and an upper end of the fillet portion UF2_F may be higher than a lower surface of the second semiconductor die CH2. When viewed in a plan view of FIG. 1, a width of the fillet portion UF2_F of the second under-fill layer UF2 may be widest at a center of the side surface of the second semiconductor die CH2 and may become narrowed toward an edge of the second semiconductor die CH2.

The first under-fill layer UF1 and the second under-fill layer UF2 may comprise a non-conductive film (NCF). The first under-fill layer UF1 and the second under-fill layer UF2 may each be called a ‘non-conductive layer.’ The first under-fill layer UF1 and the second under-fill layer UF2 may each independently include a thermosetting resin or a photocurable resin. Additionally, the first under-fill layer UF1 and the second under-fill layer UF2 may each independently further include an organic filler or an inorganic filler. The organic filler may include, for example, a polymer material. The inorganic filler may include, for example, silicon oxide (SiO₂).

For example, referring to FIG. 3B, the resin forming the first under-fill layer UF1 may be different from the resin forming the second under-fill layer UF2. First fillers PC1 dispersed in the first under-fill layer UF1 may have different sizes (average size, or diameter), shapes, and material from those of second fillers PC2 dispersed in the second under-fill layer UF2. Some of the first fillers PC1 may protrude outside the upper surface UF1_US of the first under-fill layer UF1. Some of the first fillers PC1 may exist at the interface between the first under-fill layer UF1 and the second under-fill layer UF2. That is, some of the first fillers PC1 may be in contact with the first under-fill layer UF1 and the second under-fill layer UF2, simultaneously. The upper surface UF1_US of the first under-fill layer UF1 may have a first surface roughness. The upper surface UF2_US of the second under-fill layer UF2 may have a second surface roughness that is smaller than the first surface roughness. As a result, the surface area of the upper surface UF1_US of the first under-fill layer UF1 may be increased, thereby improving adhesion between the first under-fill layer UF1 and the second under-fill layer UF2.

Referring to FIG. 1, the first semiconductor die CH1 may have a first width WT1 in the first direction X. The first under-fill layer UF1 may have a second width WT2 that is smaller than the first width WT1 in the first direction X. The second under-fill layer UF2 may have a third width WT3 that is smaller than the second width WT2 in the first direction X. The second semiconductor die CH2 may have a fourth width WT4 that is smaller than the third width WT3 in the first direction X.

In the semiconductor package 1000 according to one or more example embodiments, an upper surface of the second redistribution dielectric layer IL2 may be curved by the first redistribution patterns RP1. A height of the upper surface of the second redistribution dielectric layer IL2 disposed on the first redistribution patterns RP1 may be relatively higher than a height of an upper surface of the second redistribution dielectric layer IL2 disposed on an edge of a backside of the first semiconductor die CH1. Due to this height difference, a distance between the second semiconductor die CH2 and the first semiconductor die CH1 at the edge of the second semiconductor die CH2 may be relatively great.

When the under-fill layer interposed between the second semiconductor die CH2 and the first semiconductor die CH1 is formed of a single layer, it may increase the possibility that a space below the edge of the second semiconductor die CH2 is unfilled with the under-fill layer. This may be called an unfill problem. This unfill problem may cause cracks or peeling of the mold layer and deteriorate reliability of the semiconductor package. When a thickness of the under-fill layer with a single-layer structure is increased in order to prevent the unfill problem, a width of the fillet portion of the under-fill layer also may be widened and thus there is a risk that the fillet portion of the under-fill layer is exposed at the side surface of the mold layer, which may cause deterioration with the reliability of the semiconductor package. Additionally, when the thickness of the under-fill layer is increased, it may increase the possibility of non-wet defects occurring in which the second solder layer 113 is not in contact with the second conductive pad CP. This reduces the reliability of the semiconductor package.

However, in one or more example embodiments, the under-fill layer has a double-layer structure of the first under-fill layer UF1 and the second under-fill layer UF2. A space between the first semiconductor die CH1 and the second semiconductor die CH2 may be narrowed by the first under-fill layer UF1. As a result, a thickness of the second under-fill layer UF2 may be relatively reduced, and a width of the fillet portion UF2_F of the second under-fill layer UF2 may also be narrowed. Accordingly, the second under-fill layer UF2 may not be exposed at the side surface of the first mold layer MD1, and the possibility of non-wet defects may be reduced. Additionally, the first under-fill layer UF1 is not exposed to the side of the first mold layer MD1 due to the first dam DM1. As a result, the reliability of the semiconductor package 1000 may be improved.

Herein, the under-fill layer has the double-layer structure of the first under-fill layer UF1 and the second under-fill layer UF2, but the under-fill layer may have a multi-layer structure of three or more layers.

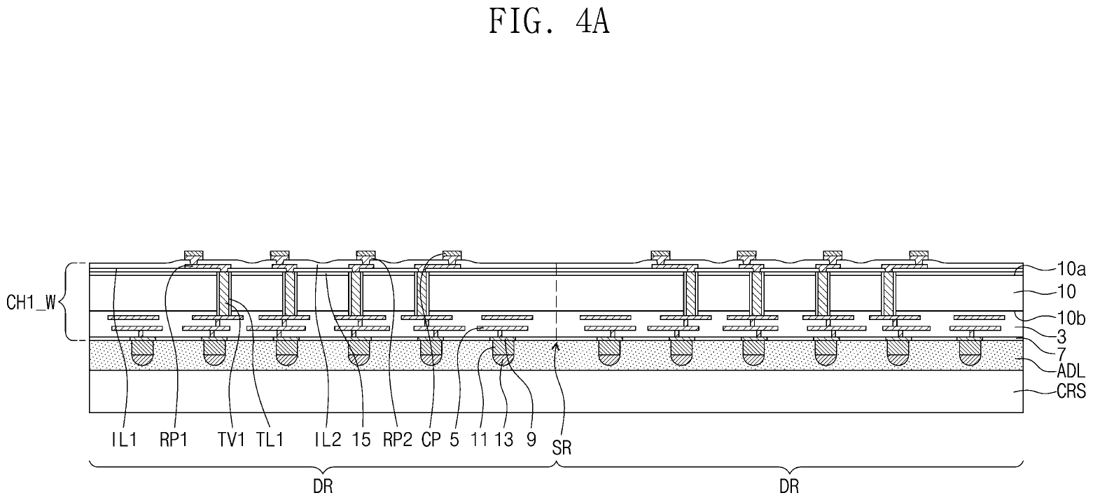

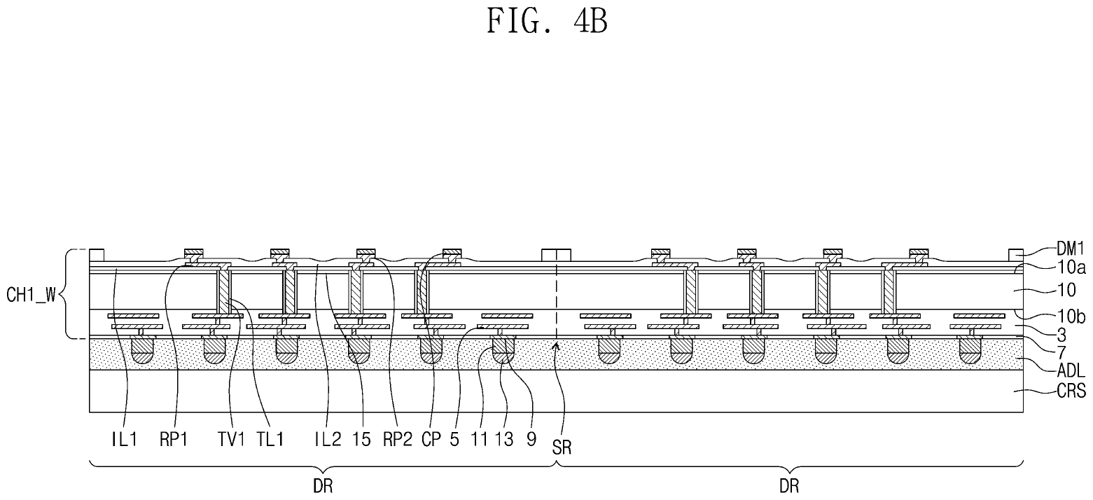

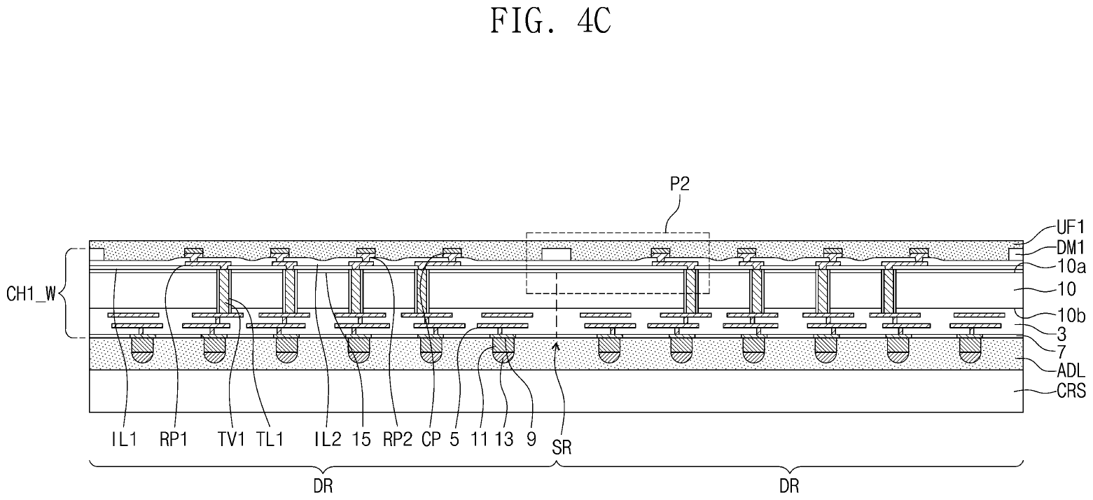

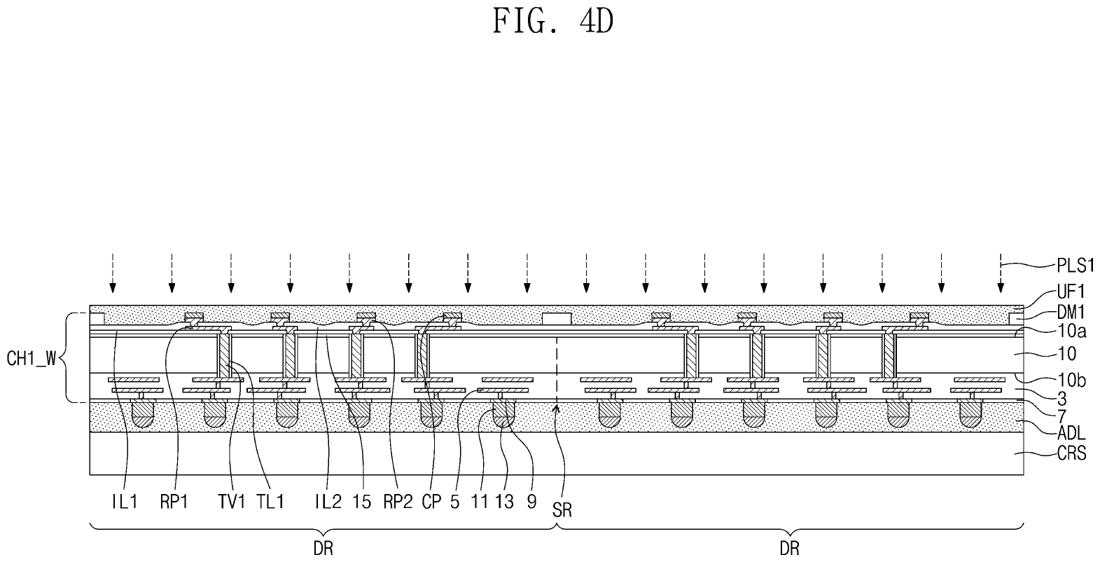

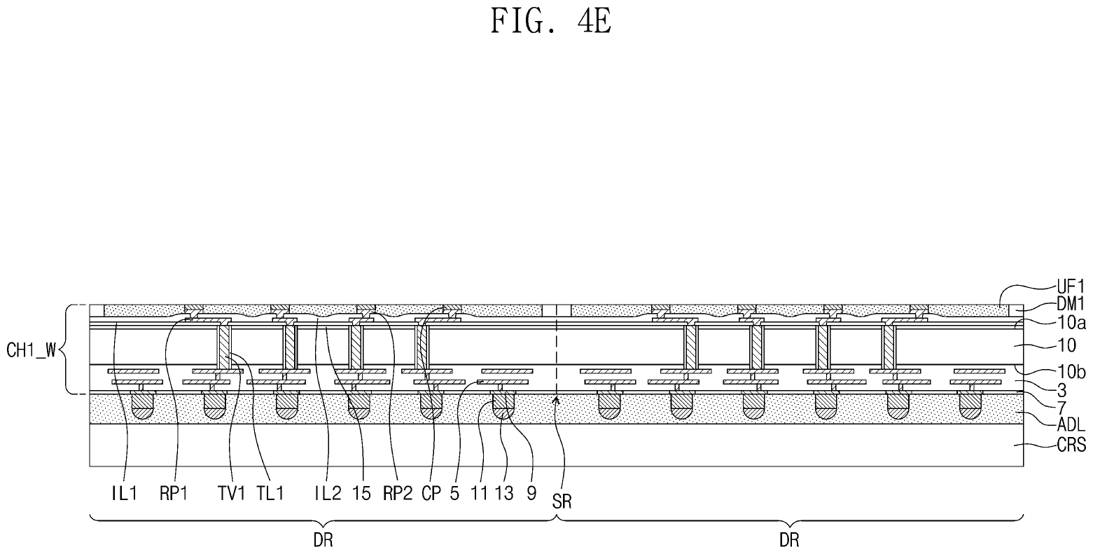

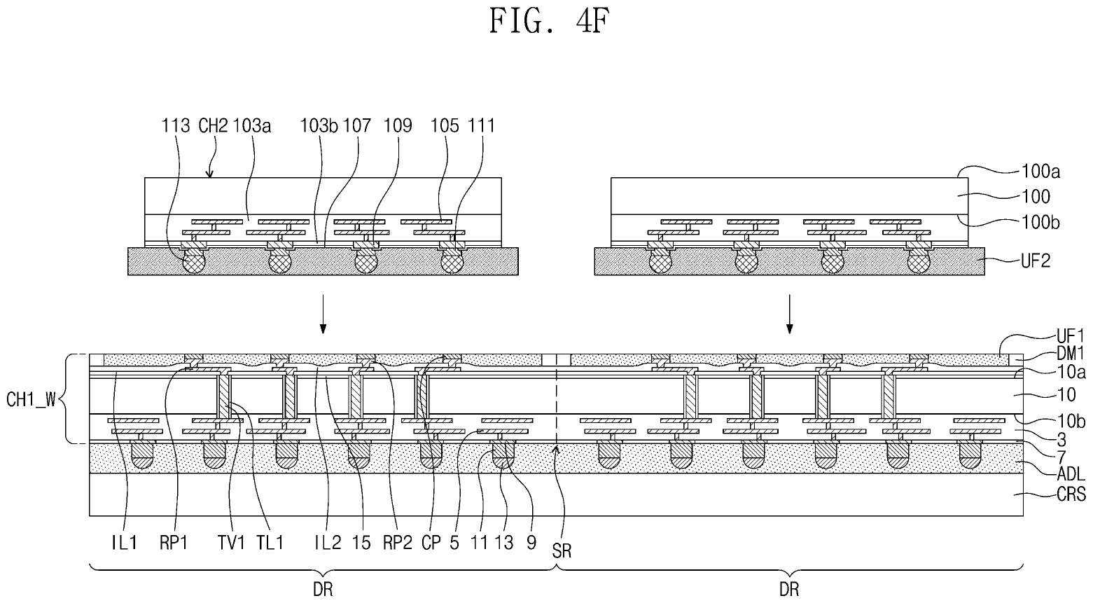

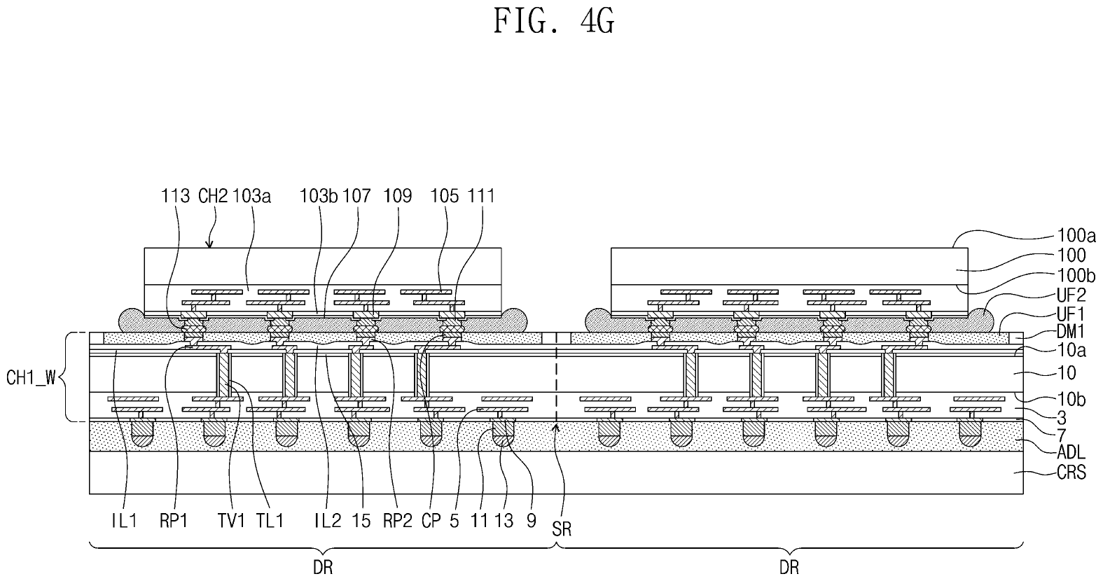

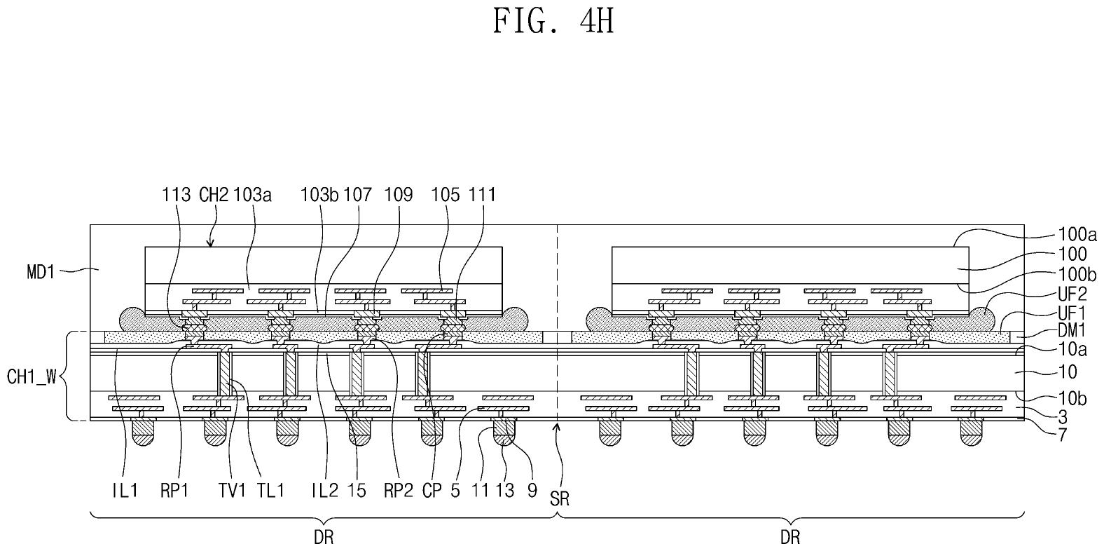

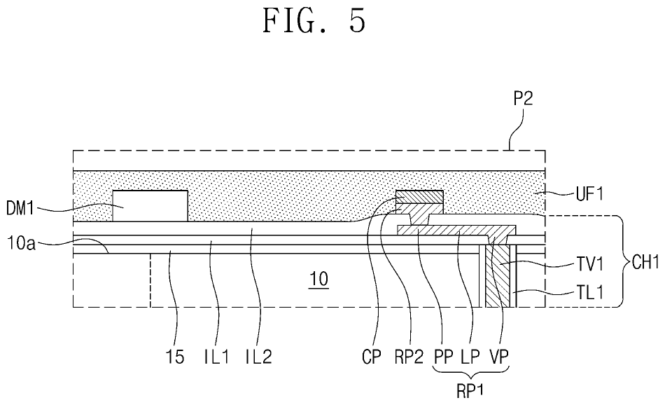

FIGS. 4A, 4B, 4C, 4D, 4E, 4F, 4G and 4H are views sequentially illustrating a process for manufacturing the semiconductor package of FIG. 2 according to one or more example embodiments. FIG. 5 is an enlarged view of ‘P2’ in FIG. 4C.

Referring to FIG. 4A, a wafer CH1_W for a first semiconductor die is prepared. The first semiconductor die wafer CH1_W may have device regions DR and a separation region SR between device regions DR. The first semiconductor die wafer CH1_W, in each device region DR, may have the internal structure described with reference to one or more example embodiments of FIG. 2. A first through via TV1 and a first via insulating layer TL1 may be formed in the first semiconductor die wafer CH1_W. On a front surface 10b of the first substrate 10 of the first semiconductor die wafer CH1_W, a first interlayer insulating layer 3, first interconnection lines 5, a first passivation layer 7, first conductive pads 9, first conductive bumps 11, and first solder layer 13 may be formed. The first semiconductor die wafer CH1_W may be bonded to a carrier substrate CRS through an adhesive layer ADL. A back surface 10a of the first substrate 10 of the first semiconductor die wafer CH1_W may be ground to expose the first through via TV1 and the first via insulating layer TL1 and to form a first backside insulating layer 15.

A first redistribution dielectric layer IL1 may be formed on the first backside insulating layer 15. The first redistribution dielectric layer IL1 may be formed of a photo imageable dielectric (PID) resin. An exposure and development process may be performed to form first via holes exposing the first through vias TV1 in the first redistribution dielectric layer IL1. A first mask pattern defining planar shapes of the first redistribution patterns RP1 may be formed on the first redistribution dielectric layer IL1, and a plating process may be performed to form the first redistribution patterns RP1. Then, the first mask pattern may be removed. Some of the first redistribution patterns RP1 may fill the first via holes.

A second redistribution dielectric layer IL2 may be formed on the first redistribution dielectric layer IL1 and the first redistribution patterns RP1. The second redistribution dielectric layer IL2 may be formed of a photo imageable dielectric (PID) resin. An upper surface of the second redistribution dielectric layer IL2 may be formed to be curved by the first redistribution patterns RP1. An exposure and development process may be performed to form second via holes exposing the first redistribution patterns RP1 in the second redistribution dielectric layer IL2. A second mask pattern defining planar shapes of the second redistribution patterns RP2 may be formed on the second redistribution dielectric layer IL2, and plating processes may be performed to form the second redistribution patterns RP2 and second conductive pads CP. Then, the second mask pattern may be removed. Some of the second redistribution patterns RP2 may fill the second via holes.

Referring to FIG. 4B, a first dam DM1 may be formed on the second redistribution dielectric layer IL2. The first dam DM1 may be formed of a photo imageable dielectric (PID) resin. The first dam DM1 may be formed by coating a photosensitive insulating resin and then performing an exposure and development process. The first dam DM1 may be formed to overlap the separation region SR and to expose the device regions DR. The first dam DM1 of FIG. 4B may be formed to have a grid shape when viewed in a plan view.

Referring to FIGS. 4C and 5, a first under-fill layer UF1 may be formed on the first semiconductor die wafer CH1_W. The first under-fill layer UF1 may be formed by laminating a non-conductive film (NCF) in a heated state. The first under-fill layer UF1 may be formed to cover the first dam DM1, the second redistribution dielectric layer IL2, the second redistribution patterns RP2, and the second conductive pads CP. In one or more example embodiments, the first under-fill layer UF1 may be formed to have a flat upper surface.

Referring to FIGS. 4D and 4E, the first etching process PLS1 may be performed to remove an upper portion of the first under-fill layer UF1 to expose upper surfaces of the first dam DM1 and second conductive pads CP. The first etching process PLS1 may be a plasma etching process using, for example, oxygen (O₂) or CF₄. Due to the first etching process PLS1, an upper surface UF1_US of the first under-fill layer UF1 may have a relatively large surface roughness, as illustrated in FIG. 3B. Additionally, some of the first fillers PC1 dispersed in the first under-fill layer UF1 may be exposed through the first etching process PLS1.

Referring to FIG. 4F, second semiconductor dies CH2 are prepared. Each of the second semiconductor dies CH2 may have the same structure as described with reference to one or more example embodiments of FIG. 2. Each of the second semiconductor dies CH2 may include a second substrate 100, a second interlayer insulating layer 103a, second interconnection lines 105, a third interlayer insulating layer 103b, a second passivation layer 107, third conductive pads 109, second conductive bumps 111, and second solder layers 113. A second under-fill layer UF2 may be formed below the second semiconductor dies CH2. The second under-fill layer UF2 may be formed by laminating a non-conductive film (NCF) in a heated state. According to one or more example embodiments, an edge of the second under-fill layer UF2 may have a right-angled cross section. The second under-fill layer UF2 may be formed to cover the second passivation layer 107, the second conductive bumps 111, and the second solder layers 113. The second semiconductor dies CH2 on which the second under-fill layer UF2 may be formed are disposed to correspond to each other on the device regions DR of the first semiconductor die wafer CH1_W.

Referring to FIG. 4G, a thermocompression process may be performed, and thus the second solder layers 113 of the second semiconductor dies CH2 penetrate the second under-fill layer UF2 and are bonded on the second conductive pads CP. According to one or more example embodiments, a flux agent included in the NCF, which is the second under-fill layer UF2, may remove an oxide layer on surfaces of the second solder layers 113 and/or the second conductive pads CP. In the thermal compression process, NCF, which is the second under-fill layer UF2, may also be compressed in a partially melted state and may protrude to have a fillet portion (UF2_F in FIG. 3A) with a round cross-section next to the second semiconductor dies CH2.

In the method of manufacturing a semiconductor package according to one or more example embodiments, a space between the first semiconductor die CH1 and the second semiconductor die CH2 may be narrowed by the first under-fill layer UF1. As a result, a thickness of the second under-fill layer UF2 may be relatively reduced, and a width of the fillet portion UF2_F of the second under-fill layer UF2 may also be narrowed. Accordingly, the second under-fill layer UF2 may not be exposed to the side of the first mold layer MD1, and the possibility of non-wet defects may be reduced. Additionally, the first under-fill layer UF1 is not exposed to the side of the first mold layer MD1 due to the first dam DM1. As a result, the reliability of the semiconductor package 1000 may be improved.

Referring to FIG. 4H, a first mold layer MD1 may be formed on the first semiconductor die wafer CH1_W using a mold. Subsequently, the adhesive layer ADL and the carrier substrate CRS are removed from the first semiconductor die wafer CH1_W. Then, a singulation process may be performed to cut the separation region SR. Therefore, the semiconductor package 1000 of FIG. 2 may be manufactured.

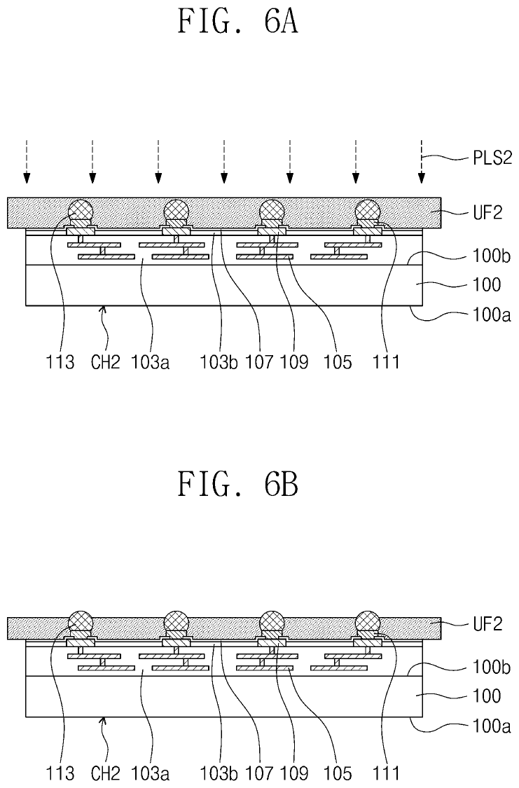

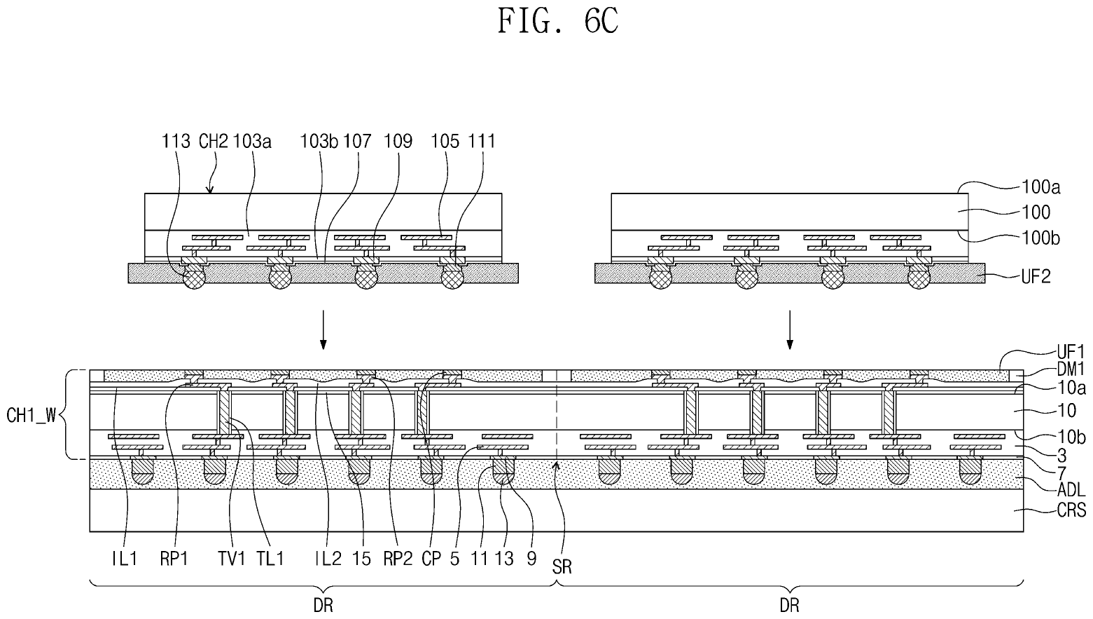

FIGS. 6A, 6B and 6C are views sequentially illustrating a process for manufacturing the semiconductor package of FIG. 2 according to one or more example embodiments.

Referring to FIGS. 6A and 6B, in FIG. 4F, while the NCF is laminated as the second under-fill layer UF2 on the second semiconductor dies CH2, a second etching process PLS2 may be performed on the second under-fill layer UF2. The second etching process PLS2 may be a plasma etching process using, for example, oxygen (O₂) or CF₄. As shown in FIG. 6B, a portion of the second under-fill layer UF2 may be removed through the second etching process PLS2 and surfaces of the second solder layers 113 may be exposed. Referring to FIG. 6C, the second semiconductor dies CH2 on which the second under-fill layer UF2 of FIG. 6B may be formed are disposed to correspond to the device regions DR of the first semiconductor die wafer CH1_W thereon. Subsequently, when a thermal compression process is performed, the second solder layers 113 of the second semiconductor dies CH2 may be bonded to the second conductive pads CP of the first semiconductor die wafer CH1_W. Then, the first mold layer MD1 may be formed, and a singulation process may be performed to cut the separation region SR. Accordingly, the semiconductor package 1000 of FIG. 2 may be manufactured.

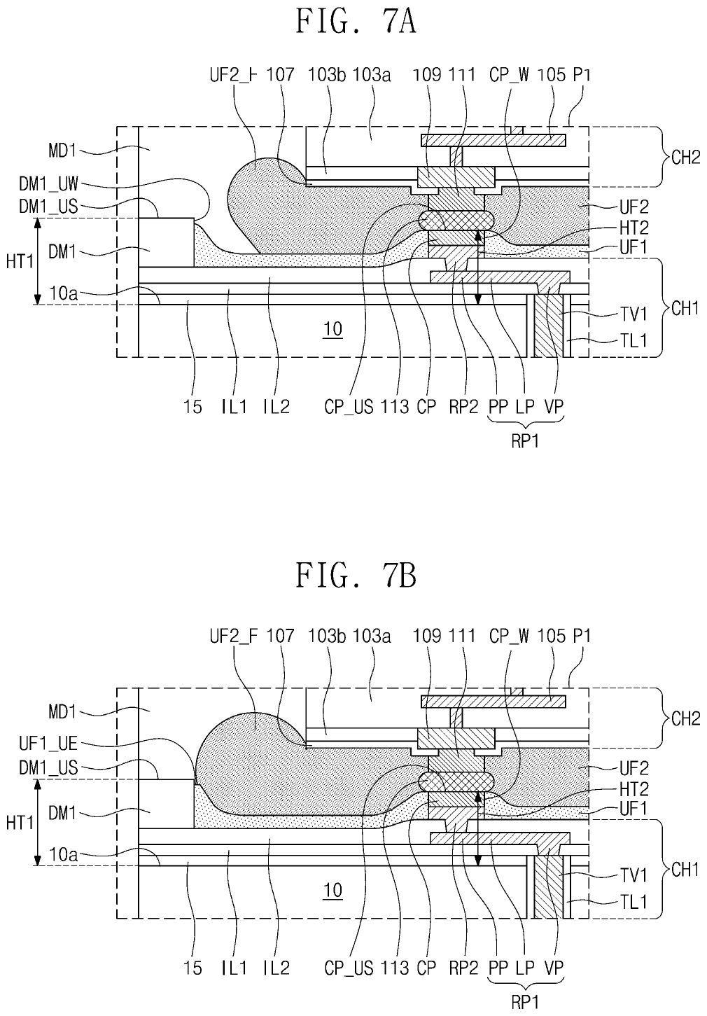

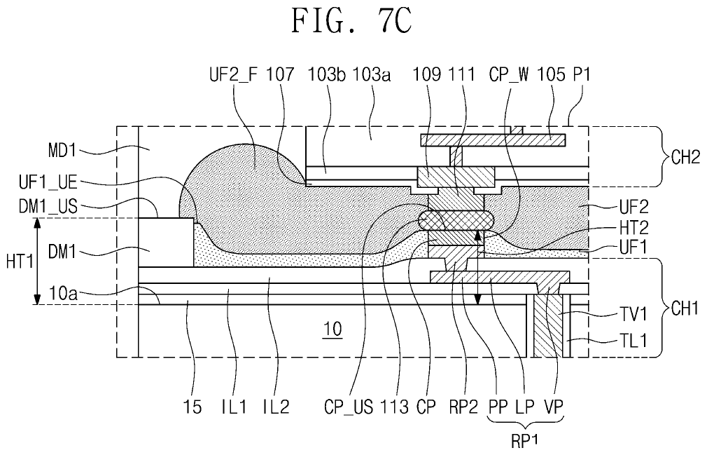

FIGS. 7A, 7B and 7C are enlarged views of portion ‘P1’ of FIG. 2 according to one or more example embodiments.

Referring to FIG. 7A, in a semiconductor package according to one or more example embodiments, the upper surface DM1_US of the first dam DM1 may have the first height H1 from the back surface 10a of the first substrate 10 of the first semiconductor die CH1. The upper surface CP_US of the second conductive pad CP may have the second height HT2 from the back surface 10a of the first substrate 10 of the first semiconductor die CH1. The second height HT2 may be smaller than the first height HT1. The upper surface of the first under-fill layer UF1 may have the concavo-convex structure. The first under-fill layer UF1 may cover the lower side of the first dam DM1 and may expose the upper side wall DM1_UW of the first dam DM1. The side surface CP_W of the second conductive pad CP may be covered with the first under-fill layer UF1. The fillet portion UF2_F of the second under-fill layer UF2 may be spaced apart from the upper sidewall DM1_UW of the first dam DM1. According to one or more example embodiments, other structures may be the same/similar to those described with reference to FIG. 2.

Referring to FIG. 7B, in the semiconductor package according to one or more example embodiments, the fillet portion UF2_F of the second under-fill layer UF2 may cover the upper end UF1_UE of the first under-fill layer UF1, and may be spaced apart from the first dam DM1. According to one or more example embodiments, other structures may be the same/similar to those described with reference to FIG. 7A.

Referring to FIG. 7C, in the semiconductor package according to one or more example embodiments, the fillet portion UF2_F of the second under-fill layer UF2 may partially cover the upper surface DM1_US of the first dam DM1, and may be spaced apart from the edge of the first mold layer MD1. According to one or more example embodiments, other structures may be the same/similar to those described with reference to FIG. 7A.

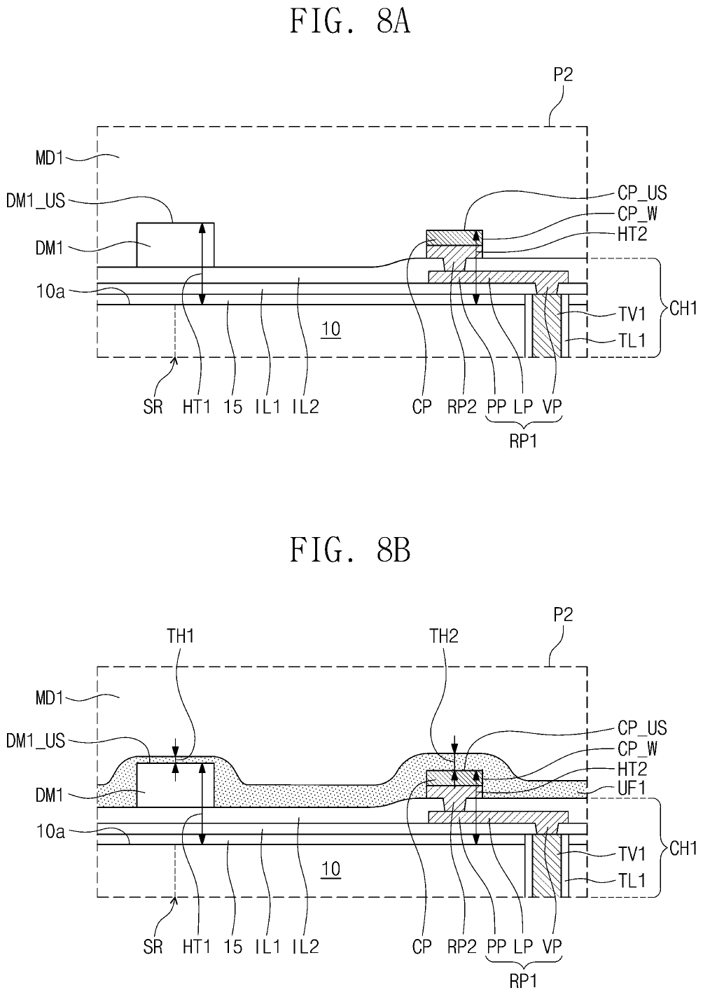

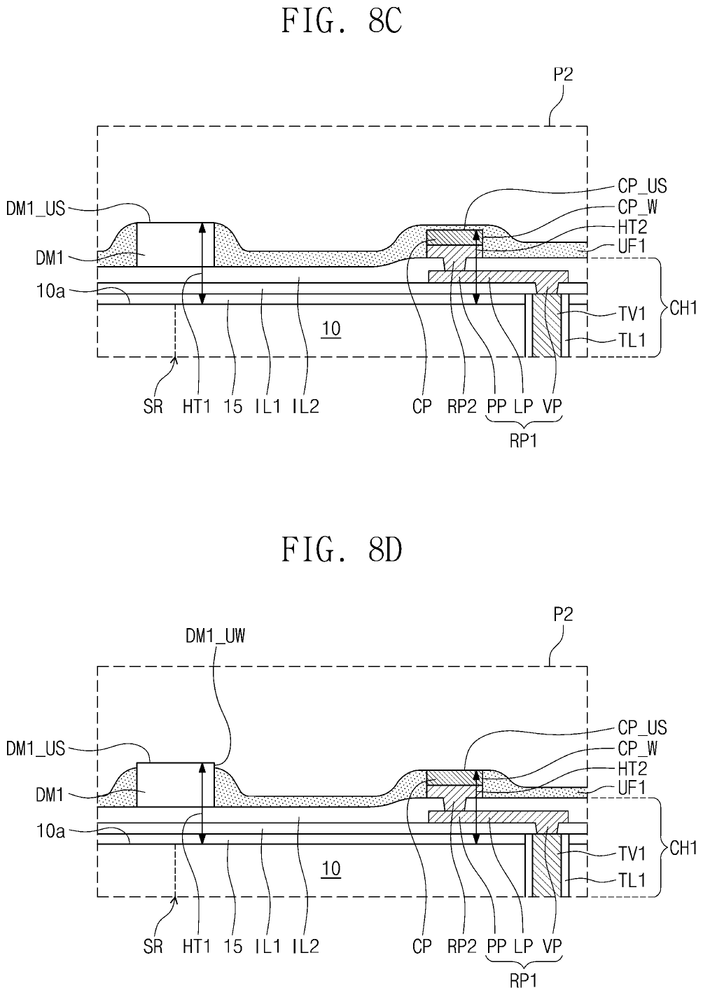

FIGS. 8A, 8B, 8C and 8D are views sequentially illustrating the process of manufacturing the semiconductor package of FIG. 7A.

Referring to FIGS. 4B and 8A, the first dam DM1 may be formed on the second redistribution dielectric layer IL2 in the state of FIG. 4A. Here, the first dam DM1 may be formed higher than the second conductive pad CP (HT1>HT2).

Referring to FIGS. 4C and 8B, the first under-fill layer UF1 may be formed on the first semiconductor die wafer CH1_W. The first under-fill layer UF1 may be formed by laminating a non-conductive film (NCF) in a heated state. The first under-fill layer UF1 may be formed to cover the first dam DM1, the second redistribution dielectric layer IL2, the second redistribution patterns RP2, and the second conductive pads CP. In one or more example embodiments, the first under-fill layer UF1 may be formed to have an irregular (concave-convex structure) profile by the first dam DM1 and the second redistribution patterns RP2. As the first dam DM1 may be formed higher than the second conductive pad CP, a difference in thickness of the first under-fill layer UF1 may occur. In detail, according to one or more example embodiments, the first under-fill layer UF1 may be formed to have a first thickness TH1 on the first dam DM1 and a second thickness TH2 on the second conductive pads CP, and the second thickness TH2 may be thicker than the first thickness TH1.

Referring to FIGS. 4D and 8C, the first etching process PLS1 may be performed to remove the upper portion of the first under-fill layer UF1 and to expose the upper surface DM1_US of the first dam DM1. However, as HT1>HT2 and TH1<TH2, the upper surface CP_US and the side surface CP_W of the second conductive pads CP may be covered with the first under-fill layer UF1.

Referring to FIG. 8D, the first etch process PLS1 is continuously performed on the first under-fill layer UF1 to expose the upper surface CP_US of the second conductive pads CP. Accordingly, a portion of the first under-fill layer UF1 covering the upper side wall DM1_UW of the first dam DM1 may be removed to expose the upper side wall DM1_UW of the first dam DM1. According to one or more example embodiments, other manufacturing processes may be the same/similar to those described above.

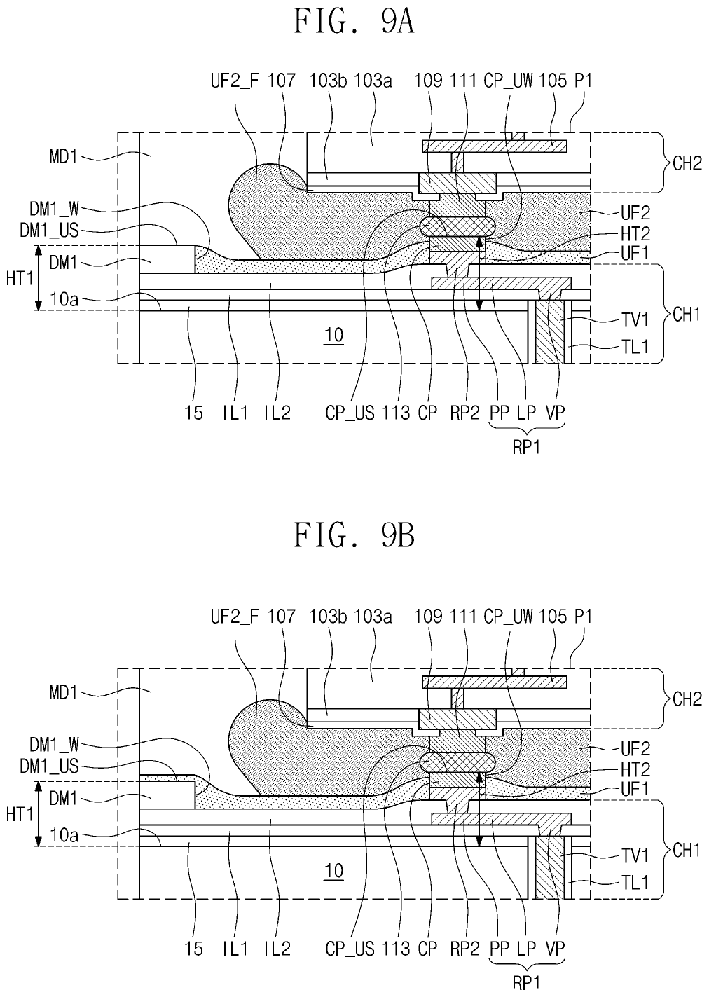

FIGS. 9A and 9B are enlarged views of portion ‘P1’ of FIG. 2 according to one or more example embodiments.

Referring to FIG. 9A, in the semiconductor package according to one or more example embodiments, the upper surface DM1_US of the first dam DM1 may have a first height HT1 from the back surface 10a of the first substrate 10 of the first semiconductor die CH1. The upper surface CP_US of the second conductive pad CP may have a second height HT2 from the back surface 10a of the first substrate 10 of the first semiconductor die CH1. The second height HT2 may be greater than the first height HT1. The upper surface of the first under-fill layer UF1 may have a concavo-convex structure. The first under-fill layer UF1 may cover the entire side wall DM1_W of the first dam DM1. The first under-fill layer UF1 may expose the upper surface DM1_US of the first dam DM1. The first under-fill layer UF1 may cover the lower side of the second conductive pad CP and expose the upper side CP_UW thereof. The fillet portion UF2_F of the second under-fill layer UF2 may be spaced apart from the first dam DM1. According to one or more example embodiments, other structures may be the same/similar to those described with reference to FIG. 2.

Referring to FIG. 9B, in a semiconductor package according to one or more example embodiments, the first under-fill layer UF1 may cover the upper surface DM1_US of the first dam DM1. According to one or more example embodiments, other structures may be the same/similar to those described with reference to FIG. 9A.

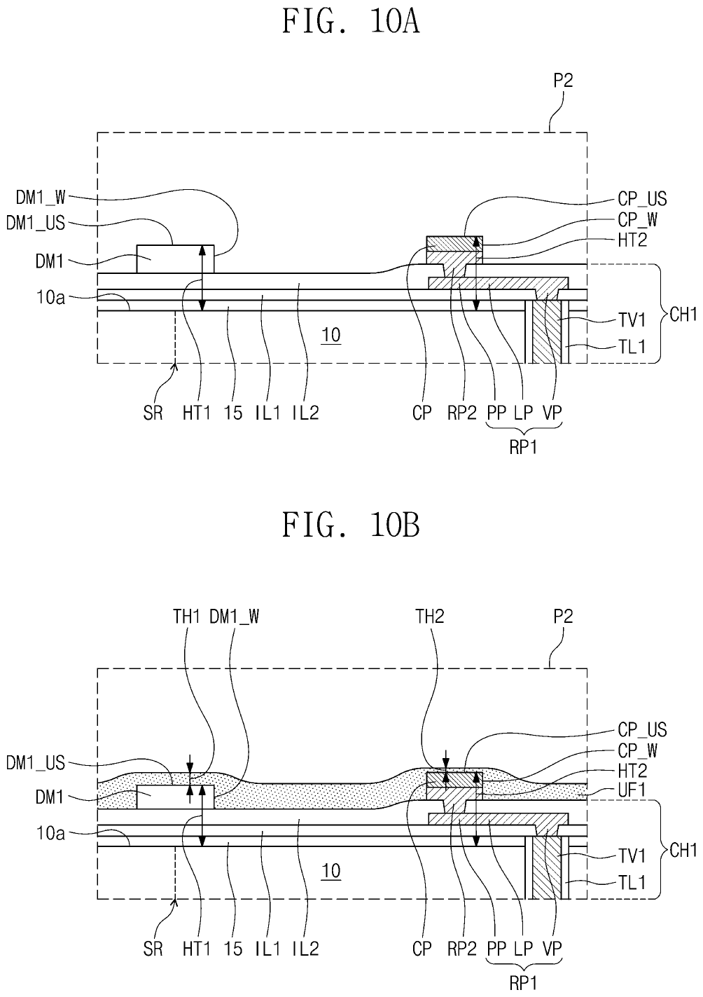

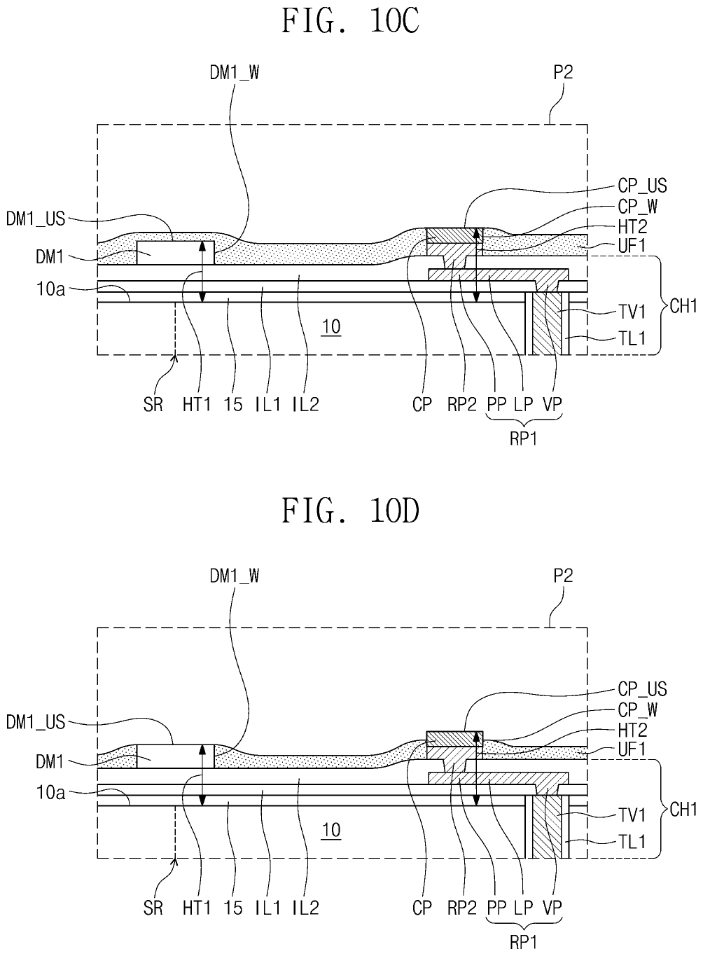

FIGS. 10A, 10B, 10C and 10D are views sequentially illustrating the process of manufacturing the semiconductor package of FIG. 9A.

Referring to FIGS. 4B and 10A, the first dam DM1 may be formed on the second redistribution dielectric layer IL2 in the state of FIG. 4A. According to one or more example embodiments, the first dam DM1 may be formed lower than the second conductive pad CP (HT1<HT2).

Referring to FIGS. 4C and 10B, the first under-fill layer UF1 may be formed on the first semiconductor die wafer CH1_W. The first under-fill layer UF1 may be formed by laminating a non-conductive film (NCF) in a heated state. The first under-fill layer UF1 may be formed to cover the first dam DM1, the second redistribution dielectric layer IL2, the second redistribution patterns RP2, and the second conductive pads CP. In one or more example embodiments, the first under-fill layer UF1 may be formed to have an irregular (concave-convex structure) profile by the first dam DM1 and the second redistribution patterns RP2. As the first dam DM1 may be formed lower than the second conductive pad CP, a difference in thickness of the first under-fill layer UF1 may occur. In detail, according to one or more example embodiments, the first under-fill layer UF1 may be formed to have a first thickness TH1 on the first dam DM1 and a second thickness TH2 on the second conductive pads CP, and the second thickness TH2 may be thinner than the first thickness TH1.

Referring to FIGS. 4D and 10C, the first etching process PLS1 may be performed to remove the upper portion of the first under-fill layer UF1 and to expose the upper surface CP_US of the second conductive pads CP. However, as HT1<HT2 and TH1>TH2, the upper surface DM1_US and the side surface DM1_W of the first dam DM1 may be covered with the first under-fill layer UF1.

Referring to FIG. 10D, the first etch process PLS1 may be continuously performed on the first under-fill layer UF1 to expose the upper surface DM1_US of the first dam DM1. As a result, a portion of the first under-fill layer UF1 covering the upper sidewall CP_UW of the second conductive pads CP may be removed to expose the upper sidewall CP_UW of the second conductive pads CP. According to one or more example embodiments, other manufacturing processes may be the same/similar to those described above.

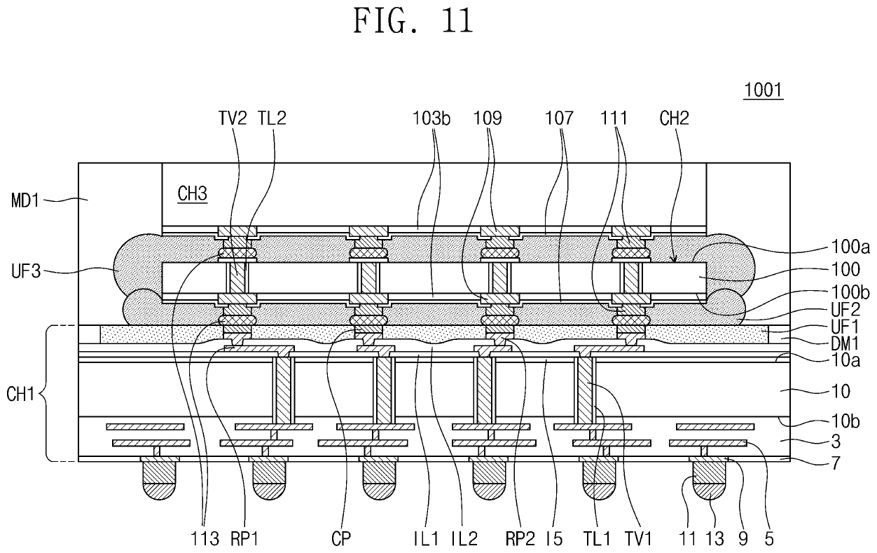

FIG. 11 is a cross-sectional view of a semiconductor package according to one or more example embodiments.

Referring to FIG. 11, a semiconductor package 1001 according to one or more example embodiments includes a first semiconductor die CH1, a first under-fill layer UF1, a second under-fill layer UF2, a second semiconductor die CH2, a third under-fill layer UF3, and a third semiconductor die CH3 that are sequentially stacked, and a first mold layer MD1 covering them. According to one or more example embodiments, the first semiconductor die CH1, the first under-fill layer UF1, and the second under-fill layer UF2 may have the same/similar structures as those described with reference to FIGS. 2, 3A, and 3B. The second semiconductor die CH2 may be similar to the second semiconductor die CH2 of FIG. 2, but may further include a second through via TV2 and a second via insulating layer TL2. The third semiconductor die CH3 may be similar to the second semiconductor die CH2, but may exclude the second through via TV2 and the second via insulating layer TL2. The third under-fill layer UF3 may fill a space between the second semiconductor die CH2 and the third semiconductor die CH3. The third under-fill layer UF3 may extend to cover the side surface of the second semiconductor die CH2 and to be in contact with an upper end of the second under-fill layer UF2. An upper surface of the first mold layer MD1 may be coplanar with an upper surface of the third semiconductor die CH3.

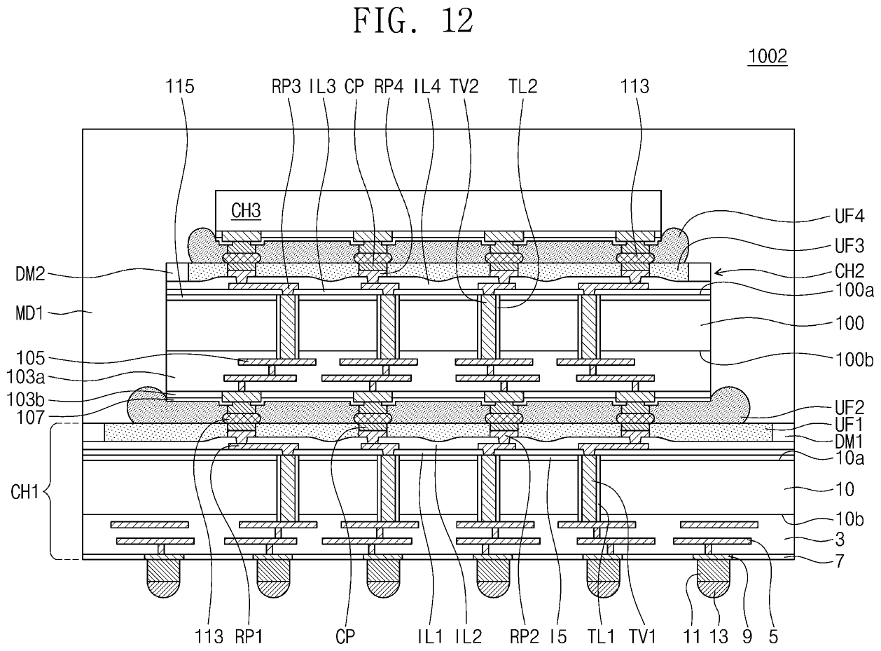

FIG. 12 is a cross-sectional view of a semiconductor package according to one or more example embodiments.

Referring to FIG. 12, a semiconductor package 1002 according to one or more example embodiments includes a first semiconductor die CH1, a first under-fill layer UF1, a second under-fill layer UF2, a second semiconductor die CH2, a third under-fill layer UF3, a fourth under-fill layer UF4, and a third semiconductor die CH3 that are sequentially stacked, and a first mold layer MD1 covering them. According to one or more example embodiments, the first semiconductor die CH1, the first under-fill layer UF1, and the second under-fill layer UF2 may have the same/similar structures as those described with reference to FIGS. 2, 3A, and 3B.

The second semiconductor die CH2 may be similar to the second semiconductor die CH2 of FIG. 2, but may further include a second through via TV2 and a second via insulating layer TL2. A second backside insulating layer 115 may be disposed on the back surface 100a of the second substrate of the second semiconductor die CH2. A third redistribution dielectric layer IL3 may be disposed on the second backside insulating layer 115. A third redistribution pattern RP3 may be disposed on the third redistribution dielectric layer IL3. A via portion VP of the third redistribution pattern RP3 may penetrate the third redistribution dielectric layer IL3 and may be in contact with the second through via TV2. A fourth redistribution dielectric layer IL4 may be disposed on the third redistribution dielectric layer IL3. An upper surface of the fourth redistribution dielectric layer IL4 may have a concave-convex structure. A fourth redistribution pattern RP4 may be disposed on the fourth redistribution dielectric layer IL4. A via portion VP of the fourth redistribution pattern RP4 may penetrate the fourth redistribution dielectric layer IL4 and may be in contact with the third redistribution pattern RP3. A second conductive pad CP may be disposed on the fourth redistribution pattern RP4. A second dam DM2 may be disposed on the fourth redistribution dielectric layer IL4. The third under-fill layer UF3 may be in contact with an upper surface of the fourth redistribution dielectric layer IL4 and a side surface of the second dam DM2. The fourth under-fill layer UF4 may be disposed on the third under-fill layer UF3. The fourth under-fill layer UF4 may be spaced apart from the second dam DM2. According to one or more example embodiments, other structures may be the same/similar to those described above.

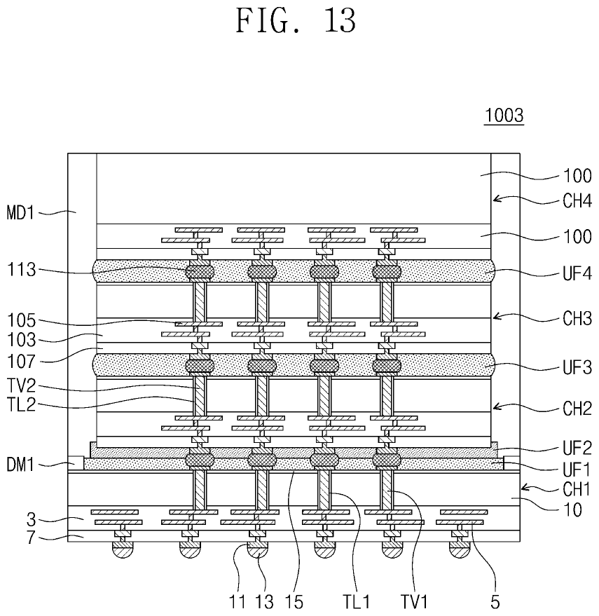

FIG. 13 is a cross-sectional view of a semiconductor package according to one or more example embodiments.

Referring to FIG. 13, a semiconductor package 1003 according to one or more example embodiments includes first, second, third and fourth semiconductor dies CH1, CH2, CH3 and CH4 sequentially stacked and a first mold layer MD1 covering them. The second, third and fourth semiconductor dies CH2, CH3 and CH4 may be memory chips that perform the same function. According to one or more example embodiments, the first semiconductor die CH1 may be identical/similar to the first semiconductor die CH1 of FIG. 2. The first semiconductor die CH1 may be a buffer die. A first dam DM1 may be disposed on an edge of the back surface of the first semiconductor die CH1. A first under-fill layer UF1 and a second under-fill layer UF2 may be interposed between the first semiconductor die CH1 and the second semiconductor die CH2. The second, third and fourth semiconductor dies CH2, CH3 and CH4 may be the same memory die. The second, third and fourth semiconductor dies CH2, CH3 and CH4 may be DRAM chips. A third under-fill layer UF3 may be interposed between the second and third semiconductor dies CH2 and CH3. A fourth under-fill layer UF4 may be interposed between the third and fourth semiconductor dies CH3 and CH4. The semiconductor package 1003 may be a high bandwidth memory (HBM) chip. According to one or more example embodiments, other structures may be the same/similar to those described above.

FIG. 14 is a cross-sectional view of a semiconductor package according to one or more example embodiments.

Referring to FIG. 14, a semiconductor package 1004 according to one or more example embodiments includes a first sub-semiconductor package PK1 and a second sub-semiconductor package PK2 stacked thereon. The first sub-semiconductor package PK1 includes a first redistribution substrate RD1, a first under-fill layer UF1, a second under-fill layer UF2, a first semiconductor die CH1, a first mold layer MD1, and mold vias MV.

The first redistribution substrate RD1 may include first, second, third and fourth redistribution dielectric layers IL1, IL2, IL3 and IL4 that are sequentially stacked. The first, second, third and fourth redistribution dielectric layers IL1, IL2, IL3 and IL4 may each comprise PID resin. An under bump UBM may be interposed within the first redistribution dielectric layer IL1. External connection terminals OB may each be bonded to the under bump UBM. The under bump UBM may comprise a conductive material. The first redistribution substrate RD1 may include first, second and third redistribution patterns RP1, RP2, and RP3. Lower surfaces of the first, second and third redistribution patterns RP1, RP2, and RP3 may be covered with a diffusion barrier layer BM. Second conductive pads CP may be disposed on the third redistribution pattern RP3. The diffusion barrier layer BM may include at least one of titanium, titanium nitride, tantalum, and tantalum nitride. The first dam DM1 may be disposed on the fourth redistribution dielectric layer IL4. The first dam DM1 may be formed of PID resin. The first dam DM1 may be disposed between the second conductive pads CP.

Mold vias MV may be disposed on the third redistribution pattern RP3 disposed at the edges thereof. The mold vias MV may penetrate the first mold layer MD1. Among the third redistribution patterns RP3, the third redistribution pattern RP3 disposed at a center thereof may be bonded to the first semiconductor die CH1. The second redistribution substrate RD2 may be disposed on the first mold layer MD1. The second redistribution substrate RD2 may include fifth, sixth and seventh redistribution dielectric layers IL5, IL6 and IL7 that are sequentially stacked. The second redistribution substrate RD2 may include fourth, fifth and sixth redistribution patterns RP4, RP5, and RP6. A second dam DM2 may be disposed on the edge of the second redistribution substrate RD2. The fifth, sixth and seventh redistribution dielectric layers IL5, IL6 and IL7 and the second dam DM2 may be formed of a PID resin.

A third under-fill layer UF3 and a fourth under-fill layer UF4 may be disposed on the second redistribution substrate RD2. According to one or more example embodiments, the third under-fill layer UF3 may be the same/similar to the first under-fill layer UF1. According to one or more example embodiments, the fourth under-fill layer UF4 may be identical/similar to the second under-fill layer UF2. The second sub-semiconductor package PK2 may be disposed on the fourth under-fill layer UF4.

The second sub-semiconductor package PK2 may include a package substrate SB, a second semiconductor die CH2 mounted thereon, and a second mold layer MD2 covering them. The second semiconductor die CH2 may be electrically connected to the package substrate SB by, for example, a wire 360. The second semiconductor die CH2 is illustrated as a single semiconductor die or semiconductor chip, but may be a semiconductor package including a plurality of semiconductor dies of the same or different types. The second semiconductor die CH2 may be one selected from an image sensor chip such as a Complementary Metal-Oxide-Semiconductor (CMOS) imaging sensor (CIS), a memory device chip such as a flash memory chip, a Dynamic Random Access Memory (DRAM) chip, a Static Random-Access Memory (SRAM) chip, an Electrically Erasable Programmable Read-Only Memory (EEPROM) chip, a Phase-Change Memory (PRAM) chip, a magnetic RAM (MRAM) chip, a Resistive RAM (ReRAM) chip, a high bandwidth memory (HBM) chip, and a hybrid memory cubic (HMC) chip, a microelectromechanical system (MEMS) device chip, or an application-specific integrated circuit (ASIC) chip.

The second mold layer MD2 may include the same material as the first mold layer MD1. The wire 360 may include copper or gold. The package substrate SB may be, for example, a double-sided or multi-layer printed circuit board. The package substrate SB may include an upper substrate pad 380 disposed on an upper surface thereof and a lower substrate pad 382 disposed on a lower surface thereof. An internal interconnection line may be disposed within the package substrate SB to connect the upper substrate pad 380 and the lower substrate pad 382. The upper substrate pad 380 and the lower substrate pad 382 may include at least one of gold, copper, aluminum, and nickel. According to one or more example embodiments, other configurations may be the same/similar to those described above.

FIG. 15 is a cross-sectional view of a semiconductor package according to one or more example embodiments.

Referring to FIG. 15, a first sub-semiconductor package PK1 included in a semiconductor package 1005 according to one or more example embodiments includes a first redistribution substrate RD1, a connection substrate 900 and a first semiconductor die CH1 mounted thereon, a first mold layer MD1 covering them, and a second redistribution substrate RD2 thereon.

The connection substrate 900 may include a cavity region CV at a center thereof. The first semiconductor die CH1 may be disposed in the cavity region CV. The connection substrate 900 may include a plurality of base layers 910 and a conductive structure 920. The base layers 910 may include an insulating material. For example, the base layers 910 may include carbon-based materials, ceramics, or polymers. The conductive structure 920 may include a connection pad 921, a first connection via 922, a connection interconnection line 923, and a second connection via 924.

A first under-fill layer UF1 and a second under-fill layer UF2 may be interposed between the connection substrate 900 and the first redistribution substrate RD1. A space between an inner wall of the cavity region CV of the connection substrate 900 and the first semiconductor die CH1 may be filled with the first mold layer MD1.

An auxiliary via 213 may penetrate the first mold layer MD1 to connect the second connection via 924 of the connection substrate 900 and the fourth redistribution pattern RP4 of the second redistribution substrate RD2. According to one or more example embodiments, other configurations may be the same/similar to those described above.

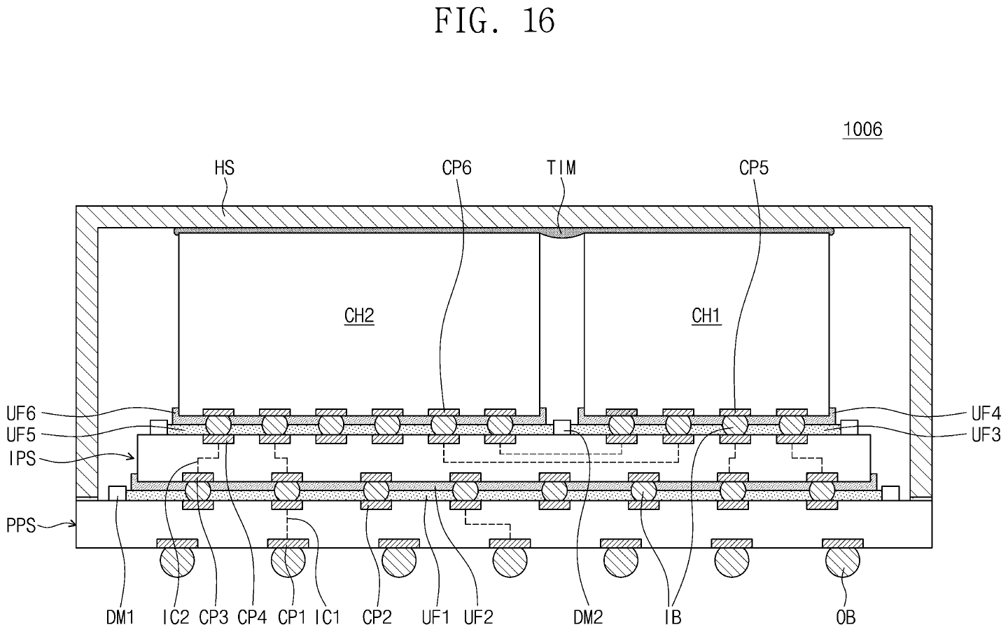

FIG. 16 is a cross-sectional view of a semiconductor package according to one or more example embodiments.

Referring to FIG. 16, a semiconductor package 1006 according to one or more example embodiments includes an interposer substrate IPS disposed on a package substrate PPS, first and second semiconductor dies CH1 and CH2 mounted on the interposer substrate IPS side by side, and a heat dissipation member HS covering them. The first and second semiconductor dies CH1 and CH2 may also be called ‘semiconductor devices’ or ‘semiconductor chips’. The first semiconductor die CH1 may be a central processing unit (CPU) chip or an application-specific integrated circuit (ASIC) chip. The second semiconductor die CH2 may be, for example, an HBM chip. The package substrate PPS and the interposer substrate IPS may each be a printed circuit board.

A first dam DM1 may be disposed on the package substrate PPS. The package substrate PPS may include first upper conductive patterns CP2 and first lower conductive patterns CP1, and first internal interconnections IC1 connecting them. External connection terminals OB may be bonded to the first lower conductive patterns CP1. The interposer substrate IPS may be bonded to the first upper conductive patterns CP2 of the package substrate PPS by internal connection terminals IB. A first under-fill layer UF1 and a second under-fill layer UF2 may be interposed between the interposer substrate IPS and the package substrate PPS.

A second dam DM2 may be disposed on the interposer substrate IPS. The interposer substrate IPS may include second upper conductive patterns CP4, second lower conductive patterns CP3, and second internal interconnections IC2. The first semiconductor die CH1 may include a first chip conductive pad CP5. The second semiconductor die CH2 may include a second chip conductive pad CP6. A third under-fill layer UF3 and a fourth under-fill layer UF4 may be interposed between the first semiconductor die CH1 and the interposer substrate IPS. According to one or more example embodiments, the third under-fill layer UF3 may be the same/similar to the first under-fill layer UF1. According to one or more example embodiments, the fourth under-fill layer UF4 may be the same/similar to the second under-fill layer UF2.

A fifth under-fill layer UF5 and a sixth under-fill layer UF6 may be interposed between the second semiconductor die CH2 and the interposer substrate IPS. According to one or more example embodiments, the fifth under-fill layer UF5 may be the same/similar to the first under-fill layer UF1. According to one or more example embodiments, the sixth under-fill layer UF6 may be the same/similar to the second under-fill layer UF2. The fourth under-fill layer UF4 and the sixth under-fill layer UF6 may be spaced apart from the second dam DM2. A thermal interface material layer (TIM) may be interposed between the heat dissipation member HS and the first and second semiconductor dies CH1 and CH2. According to one or more example embodiments, other structures may be the same/similar to those described above.

In the semiconductor package according to one or more example embodiments, the multi-layered under-fill layer is interposed between the first semiconductor die on which the backside redistribution pattern may be formed and the second semiconductor die disposed thereon. Additionally, the dam is disposed on the edge of the first semiconductor die so that the under-fill layer is not exposed to the side of the mold layer. Accordingly, the reliability of the semiconductor package may be improved.

Although one or more example embodiments are particularly shown and described above, it will be apparent to those skilled in the art that many modifications and variations in form and details may be made without departing from the spirit and scope of the following claims. Accordingly, the one or more example embodiments shown and described above should be considered in all respects as illustrative and not restrictive. Also, one or more example embodiments may be combined with each other.

What is claimed is:

1. A semiconductor package comprising:
a first semiconductor die;
a first under-fill layer on an upper surface of the first semiconductor die;
a second under-fill layer on the first under-fill layer;
a second semiconductor die on the second under-fill layer; and
a mold layer on side surfaces of the second semiconductor die, side surfaces of the second under-fill layer, and the upper surface of the first semiconductor die,
wherein the first semiconductor die comprises:
a first substrate;
a first redistribution pattern on the first substrate;
a first redistribution dielectric layer on the first redistribution pattern; and
a first dam on the first redistribution dielectric layer and an edge of the first substrate, and
wherein the first under-fill layer contacts a side surface of the first dam.

2. The semiconductor package of claim 1, wherein the second under-fill layer is spaced apart from the side surface of the first dam.

3. The semiconductor package of claim 1, wherein an upper surface of the first under-fill layer has a first surface roughness, and
wherein an upper surface of the second under-fill layer has a second surface roughness that is less than the first surface roughness.

4. The semiconductor package of claim 1, wherein the first under-fill layer comprises first fillers dispersed in the first under-fill layer,
wherein the second under-fill layer comprises second fillers, and
wherein at least one of the second fillers comprises a material that is different than a material of at least one of the first fillers or has a size that is different than a size of at least one of the first fillers.

5. The semiconductor package of claim 4, wherein at least one of the first fillers is disposed at an interface between the first under-fill layer and the second under-fill layer.

6. The semiconductor package of claim 1, wherein the first semiconductor die has a first width in a width direction,
wherein the first under-fill layer has a second width in the width direction that is less than the first width,
wherein the second under-fill layer has a third width in the width direction that is less than the second width, and
wherein the second semiconductor die has a fourth width in the width direction that is less than the third width.

7. The semiconductor package of claim 1, further comprising an internal connection member in the second under-fill layer and connecting the first semiconductor die to the second semiconductor die,
wherein the first semiconductor die further comprises:
a second redistribution pattern comprising:
a via portion penetrating the first redistribution dielectric layer and contacting the first redistribution pattern; and
a pad portion on the first redistribution dielectric layer; and
a conductive pattern on the second redistribution pattern,
wherein an upper surface of the first dam has a first height in a height direction from an upper surface of the first substrate,
wherein an upper surface of the conductive pattern has a second height in the height direction from the upper surface of the first substrate,
wherein the second height is lower than the first height, and
wherein an upper sidewall of the first dam is not covered with the first under-fill layer.

8. The semiconductor package of claim 1, further comprising an internal connection member in the second under-fill layer and connecting the first semiconductor die to the second semiconductor die,
wherein the first semiconductor die further comprises:
a second redistribution pattern comprising:
a via portion penetrating the first redistribution dielectric layer and contacting the first redistribution pattern; and
a pad portion on the first redistribution dielectric layer; and
a conductive pattern on the second redistribution pattern,
wherein an upper surface of the first dam has a first height in a height direction from an upper surface of the first substrate,
wherein an upper surface of the conductive pattern has a second height in the height direction from the upper surface of the first substrate,
wherein the first height is lower than the second height, and
wherein an upper sidewall of the conductive pattern is not covered with the first under-fill layer.

9. The semiconductor package of claim 8, wherein the first under-fill layer extends to cover an upper surface of the first dam.

10. The semiconductor package of claim 1, further comprising:
a third semiconductor die on the second semiconductor die and covered with the mold layer; and
a third under-fill layer between the second semiconductor die and the third semiconductor die,
wherein the third under-fill layer extends to contact a side surface of the second semiconductor die and an upper end of the second under-fill layer.

11. The semiconductor package of claim 1, further comprising:
a third under-fill layer on the second semiconductor die;
a fourth under-fill layer on the third under-fill layer; and
a third semiconductor die on the fourth under-fill layer,
wherein the second semiconductor die comprises a second dam provided at an edge of an upper surface of the second semiconductor die,
wherein the third under-fill layer contacts a side surface of the second dam, and
wherein the fourth under-fill layer is spaced apart from the side surface of the second dam.

12. The semiconductor package of claim 1, wherein the first dam and the first redistribution dielectric layer comprise a same material.

13. A semiconductor package comprising:
a first semiconductor die;
a first under-fill layer on an upper surface of the first semiconductor die;
a second under-fill layer on the first under-fill layer;
a second semiconductor die on the second under-fill layer;
an internal connection member in the second under-fill layer and connecting the first semiconductor die and the second semiconductor die; and
a mold layer on side surfaces of the second semiconductor die, side surfaces of the second under-fill layer, and the upper surface of the first semiconductor die,
wherein the first semiconductor die comprises:
a first substrate;
a first redistribution pattern on the first substrate;
a first redistribution dielectric layer on the first redistribution pattern;
a first dam on the first redistribution dielectric layer and provided along an edge of the first substrate;
a second redistribution pattern comprising a via portion penetrating the first redistribution dielectric layer and contacting the first redistribution pattern, and a pad portion on the first redistribution dielectric layer; and
a conductive pattern on the second redistribution pattern,
wherein the first under-fill layer contacts a side surface of the first dam,
wherein the first semiconductor die has a first width in a width direction,
wherein the first under-fill layer has a second width in the width direction that is less than the first width,
wherein the second under-fill layer has a third width in the width direction that is less than the second width, and
wherein the second semiconductor die has a fourth width in the width direction that is less than the third width.

14. The semiconductor package of claim 13, wherein an upper surface of the first dam has a first height in a height direction from an upper surface of the first substrate,
wherein an upper surface of the conductive pattern has a second height in the height direction from the upper surface of the first substrate,
wherein the second height is lower than the first height, and
wherein an upper sidewall of the first dam is not covered with the first under-fill layer.

15. The semiconductor package of claim 13, wherein an upper surface of the first dam has a first height in a height direction from an upper surface of the first substrate,
wherein an upper surface of the conductive pattern has a second height in the height direction from the upper surface of the first substrate,
wherein the first height is lower than the second height, and
wherein an upper sidewall of the conductive pattern is not covered with the first under-fill layer.

16. The semiconductor package of claim 15, wherein the first under-fill layer extends to cover an upper surface of the first dam.

17. The semiconductor package of claim 13, further comprising:
a third under-fill layer on the second semiconductor die;
a fourth under-fill layer on the third under-fill layer; and
a third semiconductor die on the fourth under-fill layer,
wherein the second semiconductor die comprises a second dam at an edge of an upper surface of the second semiconductor die,
wherein the third under-fill layer contacts a side surface of the second dam, and
wherein the fourth under-fill layer is spaced apart from the side surface of the second dam.

18. A semiconductor package comprising:
a first semiconductor die;
a first under-fill layer on an upper surface of the first semiconductor die;
a second under-fill layer on the first under-fill layer;
a second semiconductor die on the second under-fill layer; and
a mold layer on side surfaces of the second semiconductor die, side surfaces of the second under-fill layer, and the upper surface of the first semiconductor die,
wherein an upper surface of the first under-fill layer has a first surface roughness, and
wherein an upper surface of the second under-fill layer has a second surface roughness that is less than the first surface roughness.

19. The semiconductor package of claim 18, wherein the first under-fill layer comprises first fillers dispersed in the first under-fill layer,
wherein the second under-fill layer comprises second fillers, and
wherein at least one of the second fillers comprises a material that is different than a material of at least one of the first fillers or has a size that is different than a size of at least one of the first fillers.

20. The semiconductor package of claim 19, wherein at least one of the first fillers is disposed at an interface between the first under-fill layer and the second under-fill layer.
